(19) United States
(12) Patent Application Publication
(10) Pub. No.: US 2007/0057283 A1
(43) Pub. Date: Mar. 15, 2007

(54) Fed control circuit

(76) Inventors: Hideki Shiozaki, Osaka-shi (JP); Kunio Maekawa, Osaka-shi (JP)

Correspondence Address: ARMSTRONG, KRATZ, QUINTOS, HANSON & BROOKS, LLP, 1725 K STREET, NW, SUITE 1000, WASHINGTON, DC, 20006, US

(21) Appl. No.: 10/574,848

(22) PCT Filed: Oct. 6, 2003
(86) PCT No.: PCT/JP03/12763

§ 371 Date: Apr. 6, 2006

(51) Int. Cl. H01L 29/45

(52) U.S. Cl. 257/144

(57) ABSTRACT

There are provided a cathode voltage control unit 10 which controls a cathode electrode so as to uniform electron emission from the cathode electrode and a gate electrode driving unit 12 which changes a voltage of the gate electrode in response to video signals. The cathode voltage control unit 10 charges a capacitor by a constant current and determines a cathode voltage by controlling charging time. The gate electrode driving unit 12 performs ON/OFF control of the gate electrode by complementary connection.

### TECHNICAL FIELD

The present invention relates to a control circuit of a field emission display (referred to as “FED” below) and, more particularly, to a FED control circuit for controlling FED electrodes using a carbon nano-tube (referred to as “CNT” below).

### BACKGROUND ART

An FED is equivalent to a cathode ray tube assembly in which a number of cathode ray tubes are arranged and therefore, when each cathode ray tube, that is, each pixel is controlled, it can be considerable that a control circuit of a CRT, for example, as disclosed in a patent document 1 (Japanese Unexamined Patent Application Publication No. 2000-123758) is applied.

A cathode electrode and a grid electrode described in the patent document 1 are high voltage, and in the case where they are used in an FED, there are drawbacks such as noise in switching, increases in cost and in size due to use of a high breakdown voltage switch, and the like, thus countermeasures against such drawbacks are a problem.

Furthermore, in an FED, each emitter is composed of a number of CNTs, thereby tending to increase variation in characteristics; there is also variation in characteristics of a cathode electrode, gate electrode, or the like, thereby generating difference in discharge characteristics of electron beams; and consequently, there is a problem in that an uneven luminance in which luminance of each pixel is different is generated. The uneven luminance is caused by different discharge voltage between each anode electrode and cathode electrode; and there is also a problem in that a voltage to be applied between the anode electrode and the cathode electrode is adjusted to uniform discharge characteristics so that the uneven luminance is suppressed.

An object of the present invention is to provide a FED control circuit which enables a FED to reduce noise, size, and cost by reducing use of high voltage control components together with suppressing uneven luminance of the FED by correcting variation in characteristics of FED elements.

### DISCLOSURE OF THE INVENTION

According to the present invention, there is provided a FED control circuit for controlling an electrode voltage of a field emission display which includes a plurality of cathode electrodes and gate electrodes both of which being arranged in lattice shape; emitters, each of which being arranged at an intersection point of the cathode electrode and the gate electrode; fluorescent materials and anode electrodes, both of which being disposed opposing to the cathode electrode, the FED control circuit including: a cathode voltage control unit for controlling the cathode electrode so that electron emission from the cathode electrode is uniform; and a gate electrode driving unit for changing a gate electrode voltage in response to a video signal. Variation in characteristics of FED elements is corrected.

A voltage of the cathode electrode is a constant voltage (however, variation between each pixel exists) approximately a little bit higher than a voltage corresponding to work function; and a voltage of the gate electrode is the minimum control voltage which changes in response to a video signal. Furthermore, an anode electrode is a constant voltage (reference voltage). Therefore, (the cathode electrode voltage Vc+the gate electrode voltage Vg(t)) is applied to the emitter to emit necessary electrons. Electron speed is approximately corresponding to the gate electrode voltage and low; however, in the FED, a fluorescent material can be emitted by even such a voltage because distance between the cathode electrode and the anode electrode is small.

According to the FED control circuit of the present invention, uneven luminance of the FED can be suppressed by uniforming discharge characteristics by controlling the cathode voltage and the gate electrode voltage can be the minimum control voltage in response to the video signal; and therefore, high voltage control for the cathode electrode is not required, the gate electrode voltage can be reduced, and the FED can be reduced in noise, size, and cost, compared to those in which a video signal superimposed to a high voltage cathode voltage is input to a cathode electrode and a high voltage is also applied to a gate electrode (grid electrode).

The cathode voltage control unit, for example, may charge a capacitor by a constant current and determines a cathode voltage by controlling charging time. In doing so, the cathode voltage can be controlled without using a high voltage constant voltage circuit; high responsiveness, elimination of a reference voltage for every cathode, removal of spike noise, and the like can be realized; and simplified configuration can be obtained. In order to shut off the cathode electrode, the cathode electrode is refreshed by grounding the capacitor to open a capacitor voltage.

In controlling the cathode voltage, it may be preferable that charging time of the capacitor is controlled by pulse width. A pulse width generation unit, for example, may include an address counter for extracting a table memory of pulse width, the table memory of the pulse width, a pulse width determination counter for determining the pulse width, a comparator, and a control gate.

The cathode voltage control unit (CVC), more particularly, for example, includes an AND circuit (first AND circuit) for cathode electrode selection and the pulse width, an inversion circuit for inverting output of the first AND circuit, an AND circuit (second AND circuit) for cathode electrode selection and refresh, a semiconductor for operation availability determination for determining operation availability of constant current charge; a semiconductor for reset for resetting a cathode voltage; a semiconductor for constant current charge control; a semiconductor for cathode voltage retention; a semiconductor for upper limit setting for determining the upper limit of a cathode current; a constant current source for capacitor charging; and a charge and discharge capacitor of the cathode voltage.

The capacitor voltage increases in proportion to time for supplying a constant current, and therefore, the capacitor voltage can be a predetermined value by controlling time. Therefore, luminance of pixels can be uniformed by performing fine adjustment of the charging time for every pixel. Since the pulse can also be serially supplied, configuration can be simplified. Thus, each cathode electrode can be easily controlled to uniform luminance.

It may be preferable that gate electrode driving unit performs ON/OFF control of the gate electrode by complementary connection. In the FED, a number of gate electrodes exist to one cathode electrode, and thus, if a common video signal is supplied to the gate electrode, all gate electrodes on the cathode electrode are operated to generate electron emission which is straight line emission, and therefore, a gate electrode drive is required so that electron emission other than a selected gate electrode does not generate (that is, so as to be point emission). Consequently, the gate electrode is selected by performing ON/OFF of a power source of a gate driving circuit or a video signal; however, if it is performed under a high voltage as in the conventional way, a high breakdown voltage semiconductor switch is required for the number of the cathode electrodes, causing to generate electromagnetic noise. If ON/OFF control of the gate electrode is performed by complementary connection, selection of the gate electrode is performed by operation or nonoperation of a base-grounded semiconductor; and therefore, the base-grounded operation power source is controlled, so that it becomes possible to be controlled under low voltage. Thereby, it can be prevented from generating electromagnetic noise due to using a number of the high breakdown voltage semiconductor switches.

Gate electrode driving is configured so that a semiconductor for video amplification is connected to a base-grounded semiconductor in series and output of its semiconductor is connected to a semiconductor which is different in polarity from the semiconductor for video amplification; and selection of the gate electrode is performed by controlling the base grounded semiconductor. The gate electrode driving unit, more specifically, includes the semiconductor for video amplification, a semiconductor for gate selection control, the base-grounded semiconductor, a semiconductor for complementary connection formation which is different in polarity from the semiconductor for video amplification.

According to the aforementioned FED control circuit, since the video signal is input to the gate electrode, variation for every gate electrode is important, and therefore, it may be preferable that a characteristics correction unit which continuously corrects variation for every gate electrode by a data table is further included to perform correction for every gate electrode. This correction is possible by actually measuring brightness; or by measuring a current at the anode electrode, storing the obtained data in a memory as the data table, and supplying a correction value to each gate electrode in response to the data.

### BRIEF DESCRIPTION OF THE DRAWINGS

FIG. 1 is a perspective view typically showing a field emission display in which a FED control circuit according to the present invention is used;

FIG. 2 is a sectional view taken along the width direction of a cathode electrode of the same;

FIG. 3 is a sectional view taken along the width direction of a gate electrode of the same;

FIG. 4 is a block diagram showing the FED control circuit according to the present invention;

FIG. 5 is a time chart of the same;

FIG. 6 is a circuit diagram showing a cathode voltage control unit of the FED control circuit;

FIG. 7 is a time chart of the same;

FIG. 8 is a circuit diagram showing a pulse width generation unit of the FED control circuit;

FIG. 9 is a time chart of the same;

FIG. 10 is a circuit diagram showing a gate electrode driving unit of the FED control circuit;

FIG. 11 is a time chart of the same;

FIG. 12 is a block diagram showing a characteristics correction unit of the FED control circuit; and

FIG. 13 is a circuit diagram showing an example of a method of measuring cathode current.

### BEST MODE FOR CARRYING OUT THE INVENTION

Embodiments of the present invention will be described below with reference to drawings.

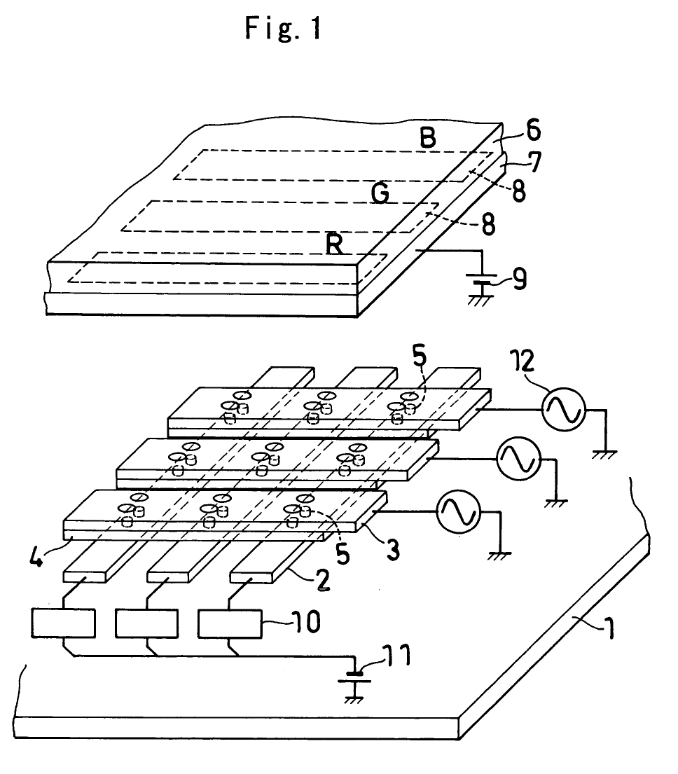

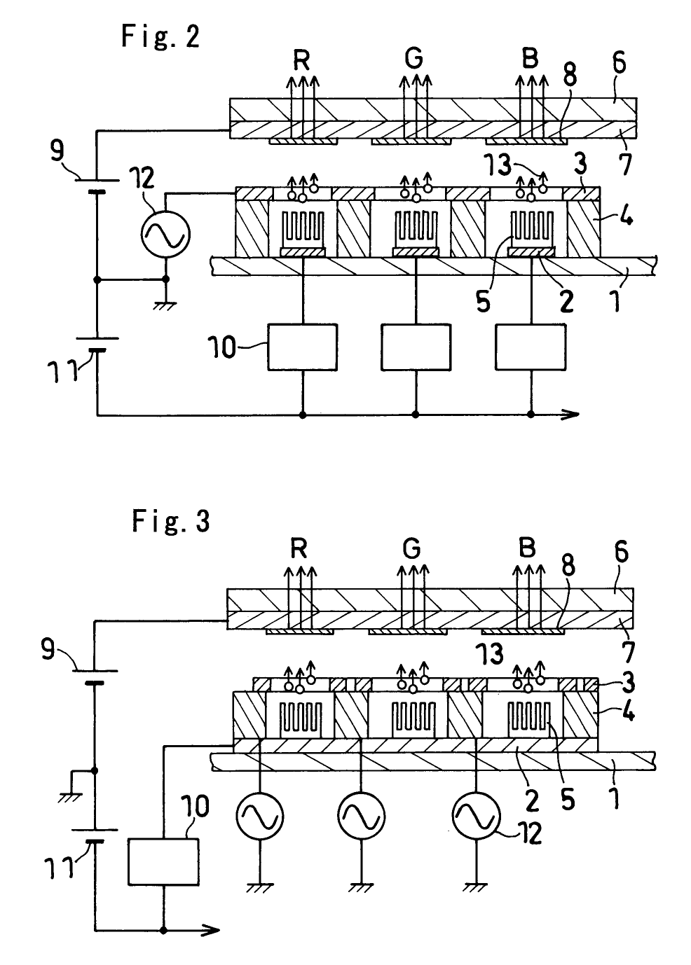

FIG. 1 to FIG. 3 show a FED (field emission display) in which a FED control circuit according to the present invention is used.

The FED includes cathode electrodes (2) and gate electrodes (3), both of which being arranged in lattice shape on a base substrate (1); insulating bodies (4), each of which being intervened between the cathode electrode (2) and the gate electrode (3); CNT (carbon nano-tube) emitter array (5), each of which being arranged at an intersection point of the cathode electrode (2) and the gate electrode (3) and connected to the cathode electrode (2); an anode electrode (7) and a luminescent fluorescent material (8), both of which being provided on a surface substrate (6); an anode power source voltage (9) for applying an anode power source to the anode electrode (7); a cathode power source voltage (11) for applying a cathode voltage to the cathode electrodes (2) via cathode voltage control units (10); and a gate electrode driving unit (12) for applying a gate voltage to the gate electrodes (3).

In luminescence operation of the FED, electron beams (13) emitted from the CNT emitter array (5) arranged on the cathode electrode (2) is controlled by the gate electrodes (3) (by supplying luminance signals) to emit by irradiating to the luminescent fluorescent material (three colors of R, B, and G) (8) on the anode electrode (7); this operation has characteristics equivalent to the cathode ray tube and the FED has configuration similar to a fine cathode ray tube assembly.

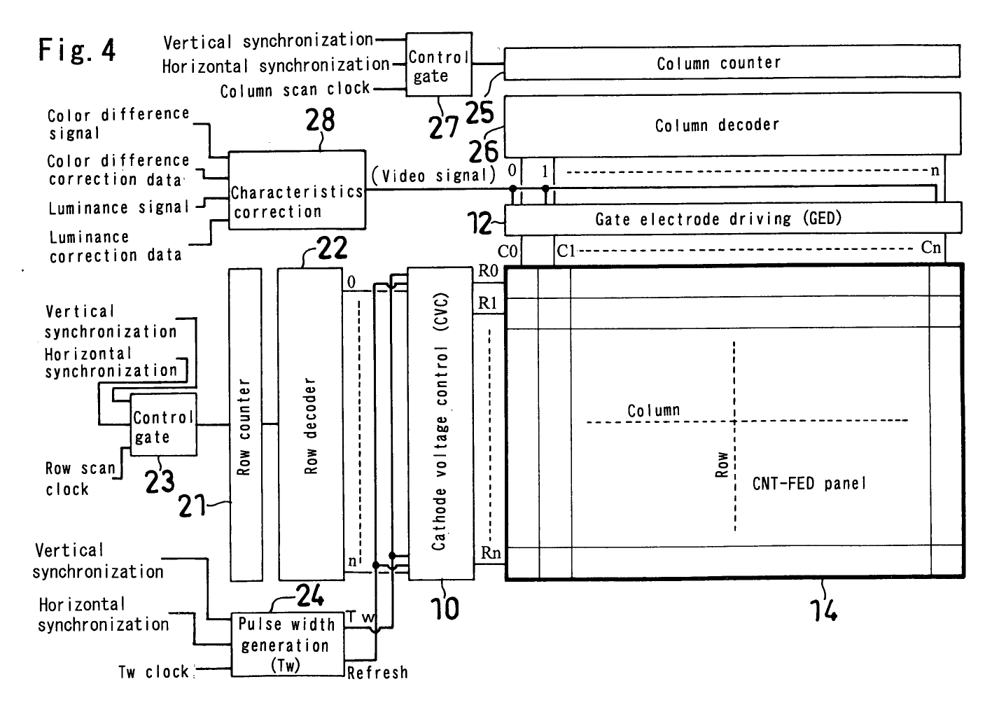

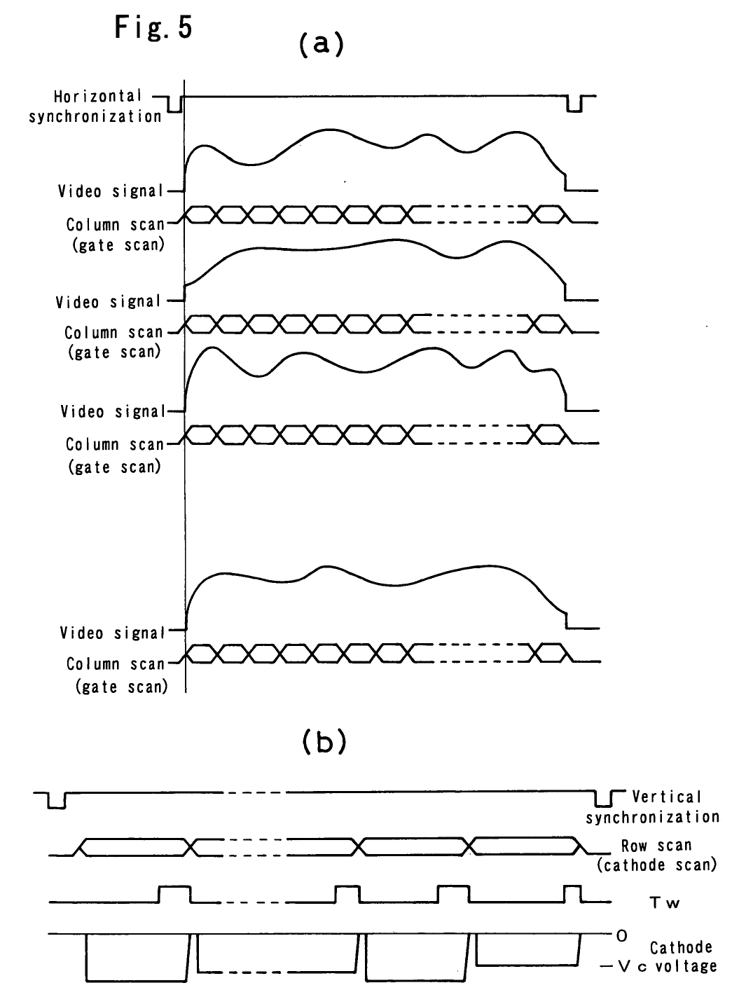

FIG. 4 shows a configuration example of the FED control circuit according to the present invention; FIG. 5 shows a simple time chart according to the FED control circuit of the present invention.

In FIG. 4, reference numeral (14) denotes a CNT-FED panel; the FED control circuit includes a row counter (21) and a row decoder (22), for selecting the cathode electrode; a row control gate (23) for controlling these; the cathode voltage control unit (CVC) (10); a pulse width (Tw) generation unit (24); a column counter (25) and a column decoder (26), for sequentially selecting the gate electrode; a control gate (27) for controlling these; the gate electrode driving unit (GED) (12); and a characteristics correction unit (28).

Voltage between the anode electrode and the cathode electrode is divided into an anode voltage and a cathode voltage and voltage control between the anode electrode and the cathode electrode is made by controlling the cathode voltage. Cathode voltage control wire and refresh wire are both made up of serial wire and data (video signals) are in a state of parallel connection.

Operation of the FED control circuit shown in FIG. 4 will be described as follows.

The row counter (21) and the row decoder (22) select the cathode electrode to control the cathode voltage. FIG. 5(b) shows a state of the cathode voltage. The selected cathode electrode appears in a horizontal scanning line. Then, the gate electrode is sequentially selected by the column counter (25) and the column decoder (26). Column scanning is shown in FIG. 5(a). Video signals are input to the selected gate electrode. Video signals are shown in FIG. 5(a). This cause electron beam emission in response to the video signals and the FED emits light.

In the aforementioned FED control circuit, the row counter (21), row decoder (22), row control gate (23), column counter (25), column decoder (26), and column control gate (27) are ordinarily configured; and the cathode voltage control unit (CVC) (10), pulse width (Tw) generation unit (24), gate electrode driving unit (GED) (12), and characteristics correction unit (28), which are features of the present invention, will be described below in detail.

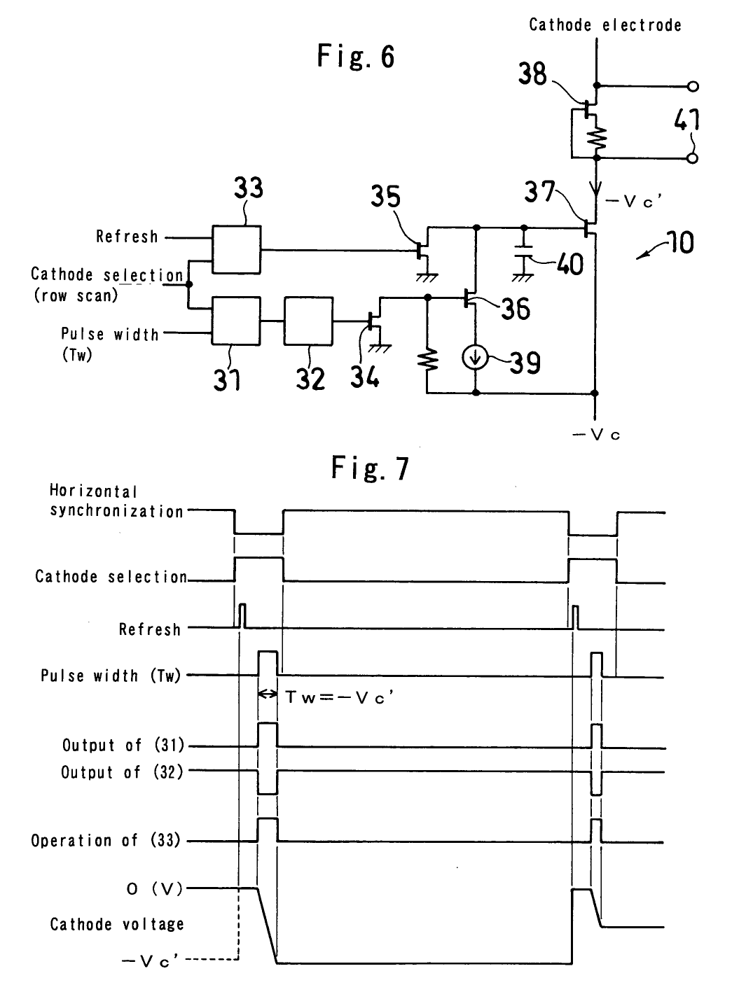

FIG. 6 shows an embodiment of the cathode voltage control unit (CVC) (10) of the FED control circuit; and FIG. 7 shows a time chart representing operation thereof.

Control principle of the cathode voltage is to charge the capacitor by a constant current and determine a cathode voltage by controlling charging time. Charging voltage (Vc) of the capacitor is shown by the following equation:
Vc=(1/C)∫Idt(V) (1)
where C is capacitor capacity, I is charging current, and t is charging time.

Then, when charging by a constant current, the equation will be as follows:
Vc=(1/C)It(V) (2)

That is, the charging voltage is proportional to charging time (t). Therefore, cathode voltage control is performed by supplying the charging time (t) by pulse and controlling the pulse time width.

As shown in FIG. 6, the cathode voltage control unit (CVC) (10) includes an AND circuit (first AND circuit) (31) for cathode electrode selection and the pulse width, an inversion circuit (32) for inverting output of the first AND circuit (31), an AND circuit (second AND circuit) (33) for cathode electrode selection and refresh, a semiconductor for operation availability determination (34) for determining operation availability of constant current charge; a semiconductor for reset (35) for resetting the cathode voltage; a semiconductor for constant current charge control (36); a semiconductor for cathode voltage retention (37); a semiconductor for upper limit setting (38) for determining the upper limit of a cathode current; a constant current source (39) for capacitor charging; a charge and discharge capacitor (40) of the cathode voltage; and a cathode current detection terminal (41) which is cathode current measurement output.

This operation will be as follows.

First, cathode selection is performed by combining a vertical synchronizing signal and a horizontal synchronizing signal. Then, a refresh is input to the second AND circuit (33) in synchronization with the horizontal synchronizing signal. Then, the semiconductor for reset (35) is operated to short-circuit the charge and discharge capacitor (40), thus the retained cathode voltage is discharged and the cathode voltage becomes zero (V). Next, pulse width (Tw) proportionate to a predetermined cathode voltage is input to the first AND circuit (31). Since the cathode selection is already performed, the pulse width (Tw) is output from the first AND circuit (31) and reach the semiconductor for operation availability determination (34) via the inversion circuit (32). Then, the same semiconductor (34) is shut off to operate the semiconductor for constant current charge control (36), thus the charge and discharge capacitor (40) is charged by a current from the constant current source (39). Then, the semiconductor for cathode voltage retention (37) is driven by the charging voltage of the capacitor (40) to generate the cathode voltage. At this time, the upper limit of the cathode current is determined by the semiconductor for upper limit setting (38) serving as a current control circuit.

Control of the cathode voltage is performed by repeating the above-mentioned operation.

Features thereof are as follows.

(1) Cathode voltage control can be performed by controlling the capacitor charging time with pulse width.

(2) Correction of variation in characteristic of the FED element (for example, fluctuation width of the cathode voltage is a variation of 20%) can be easily performed by operating the pulse width.

(3) Since control is made by the pulse width, the control wire is serial and configuration is simplified. Therefore, voltage controlling reference voltage is not required.

(4) Since the capacitor is charged after discharging, the cathode voltage is not applied to the cathode electrode which is not selected.

(5) The cathode voltage is retained between horizontal synchronizing signals, and therefore, a small charge and discharge capacitor may be used.

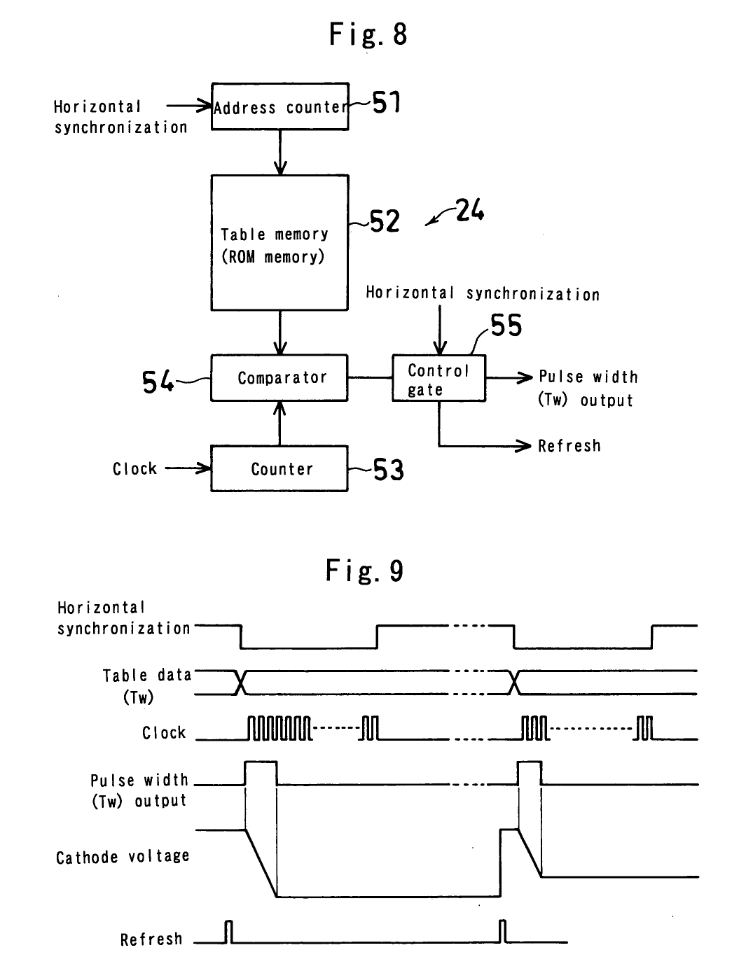

Next, an example of means for generating the pulse width in proportion to the cathode voltage will be described with reference to FIG. 8 and FIG. 9. FIG. 8 shows configuration of the pulse width (Tw) generation unit (24); FIG. 9 shows a time chart representing operation thereof.

The pulse width (Tw) generation unit (24), as shown in FIG. 8, includes an address counter (51) for extracting a table memory (52) of pulse width; the table memory (52) of the pulse width; a pulse width determination counter (53) for determining the pulse width; a comparator (54); and a control gate (55).

Operation thereof is as follows.

The address counter (51) is operated in conjunction with the horizontal synchronizing signal and a resetting refresh signal of the cathode voltage is generated. Then, pulse width data corresponding to an address counter value is output from the table memory (52) to be input to the comparator (54). Then, the pulse width determination counter (53) is operated. Since output of the counter (53) is connected to the comparator (54), if the pulse width data conforms to the counter value, a conformance signal is output to the control gate (55). Since the control gate (55) is operated in synchronization with the pulse width determination counter (53), operation is stopped by the conformance signal. That is, this operation time becomes the pulse width. The pulse width for controlling the cathode voltage can be obtained by repeating this operation.

The aforementioned pulse width for controlling the cathode voltage is determined in the following way in order to uniform the cathode current flowing from each cathode electrode by controlling the cathode voltage.

A known predetermined voltage for discharge is generated by the pulse width given by a default, and the predetermined voltage is applied to a cathode electrode as the cathode voltage. Since a number of gate electrodes are arranged to one cathode electrode, when a constant voltage is applied to the gate electrodes and the gate electrodes are sequentially scanned, the cathode current flowing from the cathode electrode fluctuates. Then, the cathode voltage is adjusted so that variation of this current becomes the minimum by operating the pulse width. When this is performed for every cathode electrode, the cathode current from each electrode is determined. Further, the cathode voltage is adjusted again by performing fine adjustment of the pulse width so that each cathode current is uniform by averaging the cathode current obtained from this. The pulse width of cathode voltage setting is determined by the aforementioned operation.

In addition, further correction of uneven luminance or the like is performed by sensitivity correction of the gate electrode.

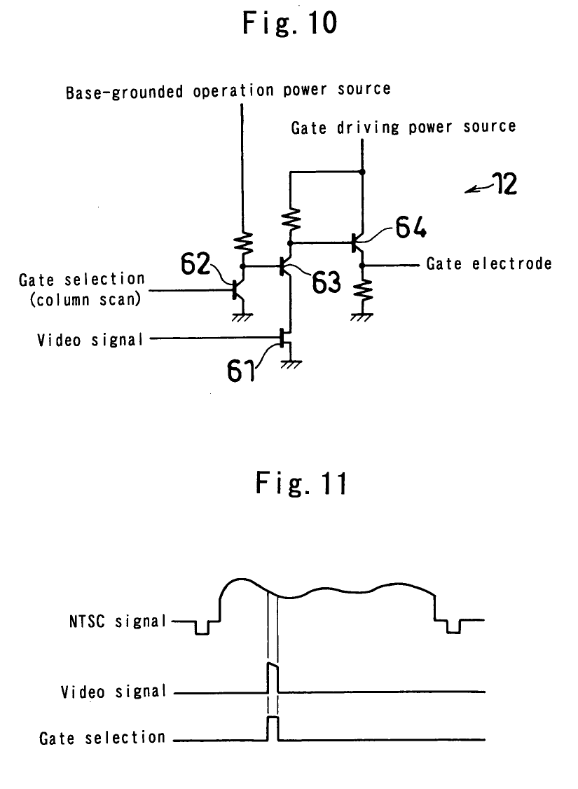

The gate electrode driving unit (12) includes two semiconductors of different polarities having complementary connection; and selection of the gate electrodes is performed by controlling a base grounded semiconductor. FIG. 10 shows configuration of the gate electrode driving unit (12); and FIG. 11 shows a time chart of operation thereof.

The gate electrode driving unit (12), as shown in FIG. 10, includes a semiconductor for video amplification (61), a semiconductor for gate selection control (62), a base grounded semiconductor (63), and a semiconductor for complementary connection formation (64) whose polarity is different from the semiconductor for video amplification (61).

Operation thereof is as follows.

When a gate selection signal is input to the semiconductor for gate selection control (62), the semiconductor for gate selection control (62) is shut off. Then, the base grounded semiconductor (63) is operated while the base is grounded. When a video signal is input to the semiconductor for video amplification (61), an inverted and amplified signal reaches the semiconductor for complementary connection formation (64) via the base grounded semiconductor (63). Since the semiconductor for complementary connection formation (64) is different in polarity from the semiconductor for video amplification (61), direct current bias is eliminated. As a result, the video signal is inverted to be supplied to the gate electrode. At this time, when the gate selection signal is eliminated, the semiconductor for gate selection control (62) is operated to shut off the base grounded semiconductor (63). Then, output of the base grounded semiconductor (63) becomes the same potential as that of a gate driving power source to shut off the semiconductor for complementary connection formation (64). Consequently, output to the gate electrode is lost.

Features thereof are as follows.

(1) In order to select the gate electrode in a state where the base grounded semiconductor of a video amplifier circuit is in an active or inactive, control of a base grounded operation power source is made. This can be controlled at low voltage.

(2) There is no possibility to emit electrons because the gate electrode is in a non voltage state when the gate electrode is not selected.

(3) If a field effect semiconductor is used in a semiconductor for a video signal input, reduction in input impedance can be relieved even when the gate electrodes are connected in a multiple parallel connection.

The characteristics correction unit (28) of the gate electrodes performs characteristic correction by synchronizing characteristic correction of a number of the gate electrodes with gate selection so that color difference signals of R, G, and B and luminance signals are individually gain-controlled by voltage using a voltage controlled amplifier.

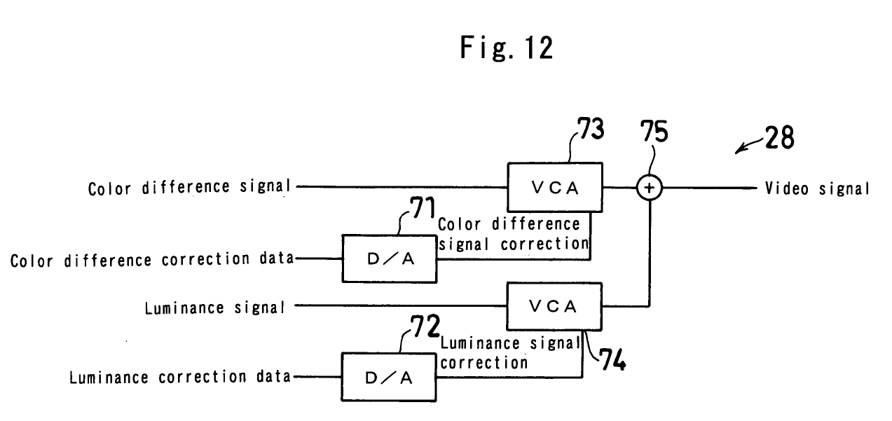

The characteristics correction unit (28), as shown in FIG. 12, includes a D/A converter (71) for converting color difference correction data to an analog value, a D/A converter (72) for converting luminance correction data to an analog value, a voltage controlled amplifier (VCA) (73) of the color difference signals, a voltage controlled amplifier (VCA) (74) of the luminance signals, and an adder (75) of the color difference signals and the luminance signals.

Operation thereof is as follows.

The color difference correction data and the luminance correction data are D/A converted respectively by the corresponding D/A converters (71) and (72) in synchronization with the gate selection. The D/A converted analog value are input to the voltage controlled amplifier (73) of the color difference signal and the voltage controlled amplifier (74) of the luminance signal. Then, the voltage controlled amplifiers (73) and (74) change gain depending on the input analog value. Then, output of the respective voltage controlled amplifiers (73) and (74) are added by the adder (75). As a result, corrected video signal can be obtained.

Features thereof are as follows.

(1) Characteristic correction data is supplied by digital amount, and therefore modification and/or change of the correction value may be performed by updating the contents of data table and the operability is high.

(2) The characteristic correction is easy because of the separation of color difference and luminance.

(3) The characteristic correction can be continuously performed, and therefore correction defects are easily detected.

A method example of extracting characteristic correction data will be described below. The characteristic correction data is extracted from electrical characteristics and luminance characteristics.

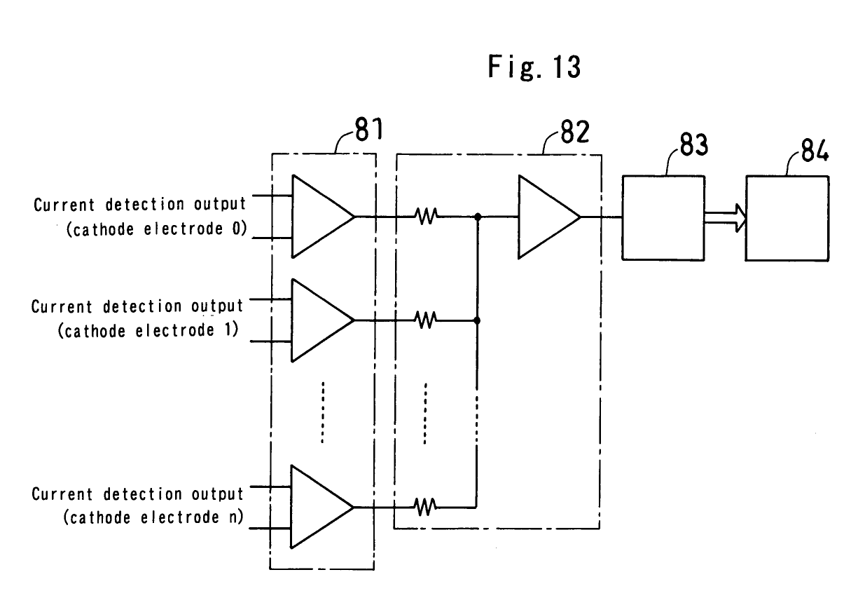

In the electrical characteristics, the cathode current is measured to extract correction data which uniforms electron emission amount. FIG. 13 shows an example of a method of measuring cathode current. Means of measuring cathode current includes an instrumentation amplifier (81) which is provided with the number of the cathode electrodes to amplify the cathode current from the cathode current detection terminal (41) of the cathode voltage control unit (10) (refer to FIG. 6) and convert to a voltage value; an adder (82) for combining the voltage-converted cathode current value; an A/D converter (83) for converting analog amount to digital amount; and a memory (84) for storing the digital-converted cathode current value.

Operation thereof is as follows.

A constant signal is supplied to the gate electrode to sequentially selectively scan the gate electrode. Then, only one cathode electrode is constantly selected, and therefore the cathode current corresponding to the selected gate electrode as the cathode current can be obtained. When this is A/D-converted, it becomes a cathode current value of digital amount. When this obtained digital value is stored in the memory, current distributions of the gate electrode disposed on one cathode electrode are determined. That is, the electrical characteristics of the gate electrode disposed on one cathode electrode can be obtained. When this is performed for all cathode electrodes, the electrical characteristics of the gate electrode can be obtained. Thereby, when this data is reflected to the data table, the characteristic correction can be performed.

In the emission characteristics, the correction data may be extracted by measuring emission luminance with a color analyzer. The correction data may also be extracted by performing luminance measurement by an optical sensor in an emission state. In each case, it is preferable to perform measurement using commercially available measuring instruments in order to obtain generalized data.

### INDUSTRIAL APPLICABILITY

In the case of being used as a control circuit of a FED (field emission display) using CNT (carbon nano-tube), variation in characteristics of the FED elements is corrected to reduce use of high voltage control components, whereby the FED can reduce noise, size, and cost.

1: A FED control circuit for controlling an electrode voltage of a field emission display which includes a plurality of cathode electrodes and gate electrodes, both of which being arranged in a lattice shape; emitters, each of which being arranged at an intersection point of said cathode electrode and said gate electrode; fluorescent materials and anode electrodes, both of which being disposed opposing to said cathode electrode, said FED control circuit comprising:
a cathode voltage control unit for controlling said cathode electrode so that electron emission from said cathode electrode is uniform; and
a gate electrode driving unit for changing a gate electrode voltage in response to a video signal.

2: The FED control circuit according to claim 1, wherein said cathode voltage control unit charges a capacitor by a constant current and determines a cathode voltage of each pixel by controlling charging time.

3: The FED control circuit according to claim 2, wherein said charging time of said capacitor is controlled by pulse width.

4: The FED control circuit according to claim 1, wherein said get electrode driving unit performs ON/OFF control of said gate electrode by complementary connection.

5: The FED circuit according to claim 1, further comprising a characteristics correction unit which continuously corrects variation for every said gate electrode by a data table.

6: The FED control circuit according to claim 2, wherein said get electrode driving unit performs ON/OFF control of said gate electrode by complementary connection.

7: The FED control circuit according to claim 3, wherein said get electrode driving unit performs ON/OFF control of said gate electrode by complementary connection.

8: The FED circuit according to claim 2, further comprising a characteristics correction unit which continuously corrects variation for every said gate electrode by a data table.

9: The FED circuit according to claim 3, further comprising a characteristics correction unit which continuously corrects variation for every said gate electrode by a data table.

10: The FED circuit according to claim 4, further comprising a characteristics correction unit which continuously corrects variation for every said gate electrode by a data table.

11: The FED circuit according to claim 6, further comprising a characteristics correction unit which continuously corrects variation for every said gate electrode by a data table.

12: The FED circuit according to claim 7, further comprising a characteristics correction unit which continuously corrects variation for every said gate electrode by a data table.
